(19) United States
(12) Patent Application Publication
(10) Pub. No.: US 2008/0111602 A1
(43) Pub. Date: May 15, 2008

(54) Cycle modulation circuit capable of limiting peak voltage

(75) Inventor: Kuo-Fan Lin, Taoyuan Hsien (TW)

Correspondence Address: BIRCH STEWART KOLASCH & BIRCH, PO BOX 747, FALLS CHURCH, VA, 22040-0747, US

(73) Assignee: SPI ELECTRONIC CO., LTD.

(21) Appl. No.: 11/599,290

(22) Filed: Nov. 15, 2006

(51) Int. Cl. H03K 3/017; H03K 3/00

(52) U.S. Cl. 327/175; 327/172

(57) ABSTRACT

A cycle modulation circuit capable of limiting peak voltage to provide a pulse width control signal to a rear end power driving unit includes a comparison unit, an input voltage source and a linear voltage generation unit. The comparison unit compares an oscillation waveform signal generated by the linear voltage generation unit against a base value of a waveform signal level generated by the input voltage source to modulate and output the pulse width control signal of a combined cycle consisting of a high level and a low level. The pulse width control signal is input to the rear end power driving unit to limit the power driving unit in an equal restricted voltage peak value zone and determine the allowable duty cycle according to the level waveform signal.

### FIELD OF THE INVENTION

The present invention relates to a cycle modulation circuit capable of limiting the peak value voltage and particularly to a cycle modulation circuit that uses a waveform signal level generated by an input voltage source as a base value to perform level comparison with an oscillation waveform signal produced by a linear voltage generation unit to generate a pulse width control signal.

### BACKGROUND OF THE INVENTION

Power supply is an indispensable element on many information products. Its most important mission is to provide sufficient and stable voltage. Otherwise equipment cannot be started normally, and unpredictable voltage and current surges can cause damage of equipment.

The conventional power supply controls the duty cycle of a power driving unit by supplying a voltage through a pulse width modulation (PWM) circuit. By controlling the switch conduction cycle of the power driving unit the peak-to-peak value of the driving voltage can be regulated. The driving voltage is the voltage at two ends of the primary coil of the transformer in the power supply. The peak value and cycle of the driving voltage greatly affect output of the power supply. If the peak-to-peak value (Vpp) of the driving voltage generated by the power driving unit is not properly controlled, or output error was excessive, the peripheral devices and semiconductor elements at the rear end could be damaged. To prevent this problem from happening, higher voltage-resistant semiconductor elements have to be used. As a result, the cost is higher. Hence controlling the peak-to-peak value (Vpp) of the driving voltage is an important issue in the research of power supply.

One of the conventional methods that is widely adopted to control the PWM circuit is “voltage second tracking method”. It is based on a principle that during power conversion multiplication product of voltage and second is equal. Hence by tracking alterations of the voltage, and feeding back the driving voltage to the PWM circuit, the PWM circuit can regulate the duty cycle through the feedback voltage to stabilize the peak-to-peak value of the driving voltage. In practice, the voltage second tracking method uses two oscillators to independently control the size of the period and voltage second. The oscillators consist of various elements such as resistors and capacitors of the same specifications. But in practice their characteristics cannot be totally the same. Every element has tolerance. As a result the oscillators are not as accurate as desired. The error of the period and voltage second controlled by the two oscillators are especially notable. Hence there is always an error on the duty cycle output by the PWM circuit compared with that derived in the ideal condition. Without a mechanism to limit the alteration range, the peak-to-peak value of the driving voltage output by the power driving unit is unstable. And the duty voltage of the peak value cannot be maintained at a constant. In the event that peak wave occurs or a great variation happens to the load, it could be mistakenly interpreted by the PWM circuit to generate a high voltage, and the rear end circuit or load could be damaged. To protect the safety of the circuit and load, more expensive high voltage-resistant semiconductor elements still have to be used on the rear end circuit. It is not economically effective.

### SUMMARY OF THE INVENTION

Therefore the primary object of the present invention is to provide a cycle modulation circuit to limit the maximum duty cycle of a PWM circuit to stabilize the peak-to-peak value of the driving voltage.

The cycle modulation circuit according to the invention mainly includes a comparison unit, an input voltage source and a linear voltage generation unit. The comparison unit has a signal input end and a signal output end. The comparison unit uses a waveform signal level generated by an input voltage source as a base value to perform level comparison with an oscillation waveform signal produced by a linear voltage generation unit, then modulates and outputs a pulse width control signal which has a combined cycle consisting of a high level and a low level. The pulse width control signal is input to a rear end power driving unit that includes the PWM circuit, thereby to limit the power driving unit in an equal restricted voltage peak value zone and determine the allowable duty cycle according to the waveform signal level.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a circuit block diagram of the invention.

FIG. 2 is a schematic circuit diagram of the invention.

FIG. 3 is a modulation chart of a pulse width control signal.

FIG. 4 is an output waveform chart of the power driving unit.

FIG. 5 is an input-cycle comparison chart.

### DETAILED DESCRIPTION OF THE PREFERRED EMBODIMENT

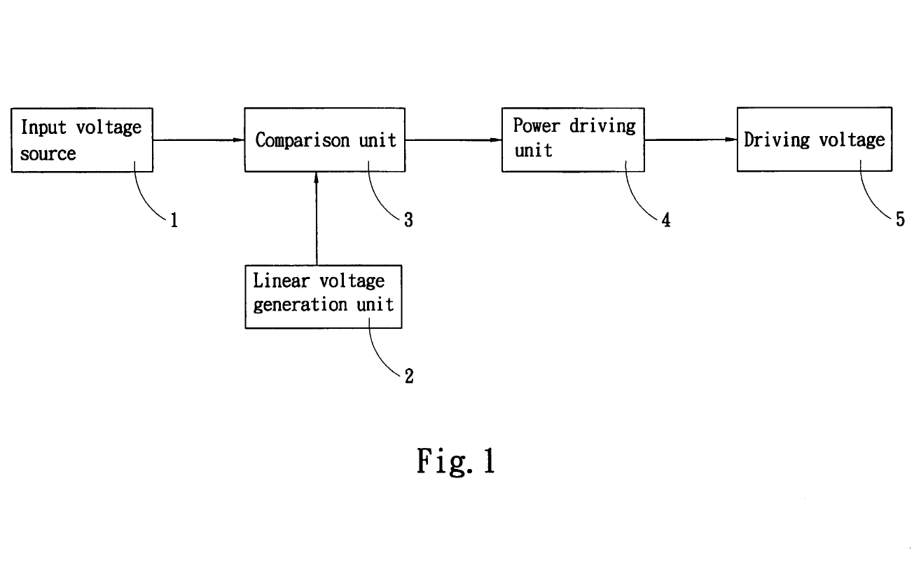

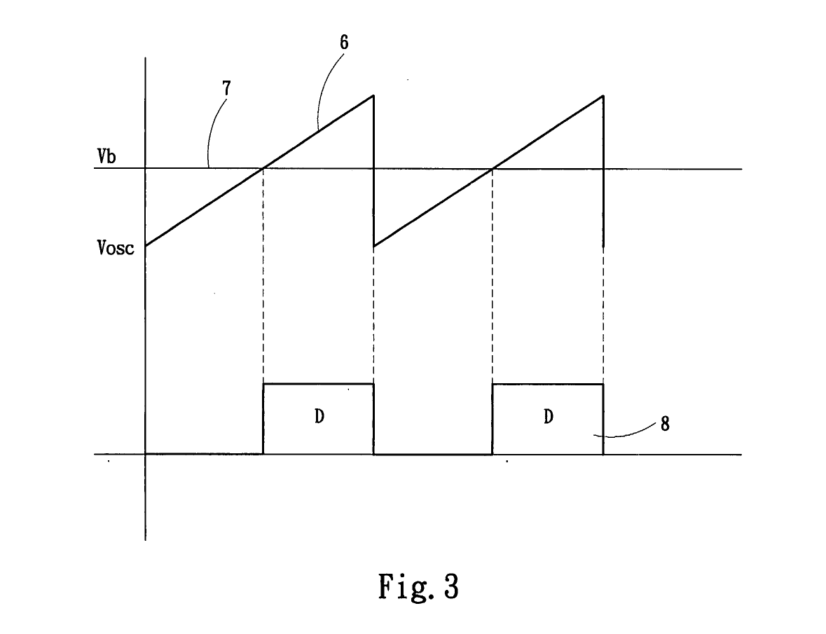

Please refer to FIGS. 1 through 4, the cycle modulation circuit capable of limiting peak voltage according to the invention aims to limit allowable maximum duty cycle of a power driving circuit to stabilize output peak-to-peak value. The circuit includes an input power source 1, a linear voltage generation unit 2 and a comparison unit 3. The input voltage source 1 generates a waveform signal level 7 through a voltage dividing unit. The comparison unit 3 compares the waveform signal level 7 and an oscillation waveform signal 6 produced by the linear voltage generation unit 2 to generate a pulse width control signal 8 which has a high level and a low level combined cycle. The pulse width control signal 8 drives a power driving unit 4 to generate a driving voltage 5.

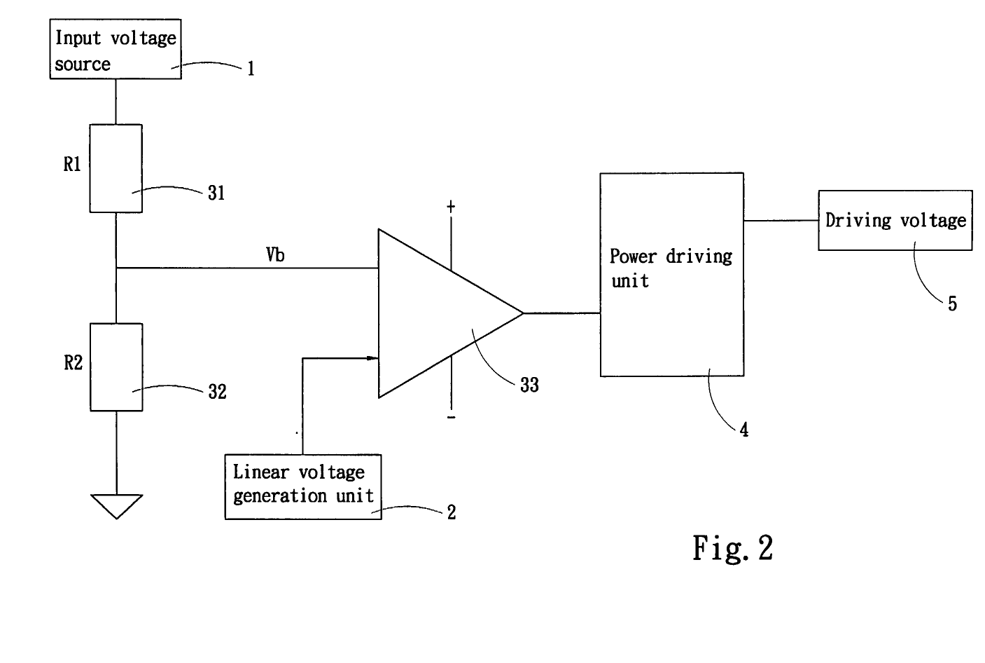

Referring to FIG. 2, the comparison unit 3 includes a process amplifier 33 which has a signal input end and a signal output end. The oscillation waveform signal 6 generated by the linear voltage generation unit 2 has a linear voltage saw type waveform with a potential difference. Through the voltage dividing unit consisting of a first component voltage resistor A31 (R1) and a second component voltage resistor B32 (R2), the waveform signal level 7 (Vb) can be obtained from the input voltage source 1. The calculation formula is as follow:

Vb=Vin×R2/(R1+R2), where Vin is gotten from the input voltage source 1

The waveform signal level 7 and the oscillation waveform signal 6 (Vosc) generated by the linear voltage generation unit 2 are input respectively to the two signal input ends of the process amplifier 33 which compares the size of the captured waveform signal level 7 (Vb) and the oscillation waveform signal 6 (Vosc) to generate the pulse width control signal 8 of a combined cycle consisting of a high level and a low level.

When the oscillation waveform signal 6 (Vosc) is greater than the waveform signal level 7, the process amplifier 33 outputs the high level. Thus the input voltage value and the high level cycle width of the pulse width control signal 8 is in inverse proportion. The pulse width control signal 8 output from the process amplifier 33 drives the power driving unit 4 to limit the allowable maximum duty cycle thereof. Moreover, the pulse width control signal 8 also affects the peak-to-peak value (Vp−p) of the driving voltage 5. The calculation formulas are as follow:

Vb=Vin×R2/(R1+R2) (1)

D=1−Vb/Vosc (2)

Vp−p=Vin(1/(1−D) (3)

By inducing (1) and (2) into (3), the outcome is:

Vp−p=Vosc(R1+R2)/R2=K

Where Vin comes from the input voltage source 1,

Vb is the waveform signal level 7,

Vosc is the oscillation waveform signal 6,

D is the high level cycle of the pulse width control signal 8, and

K is a constant.

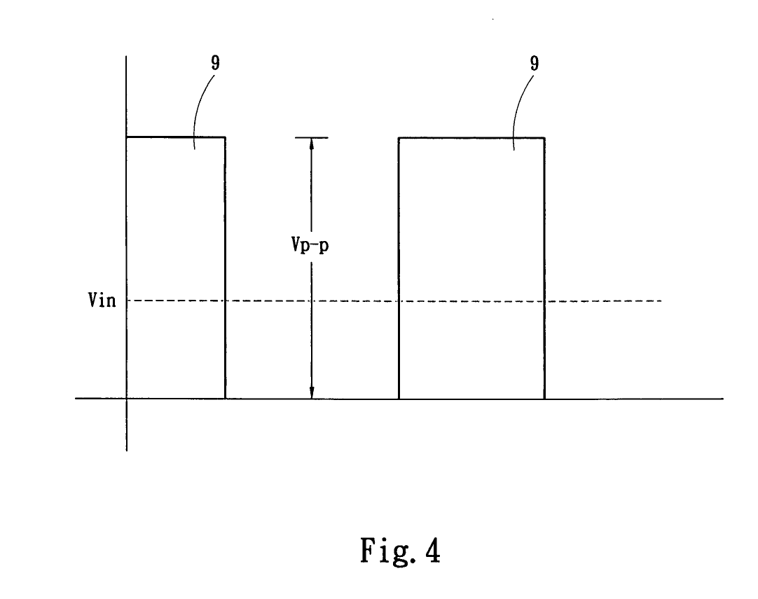

The calculation set forth above indicates that once the oscillation waveform signal 6 (Vosc) is being controlled precisely, the maximum value of Vp−p can be controlled as shown in FIG. 4 with an output waveform signal 9. The pulse width control signal 8 is determined by the waveform signal level 7 (Vb) and the oscillation waveform signal 6 (Vosc). The present technique can precisely control the peak value of the oscillation waveform signal 6 (Vosc). Hence Vp−p can be fixed and limited at a maximum value. Namely, even if the waveform signal level 7 (Vb) fluctuates constantly or has surges, the maximum value of the driving voltage 5 is not affected. Hence the driving voltage 5 does not exceed the setting range.

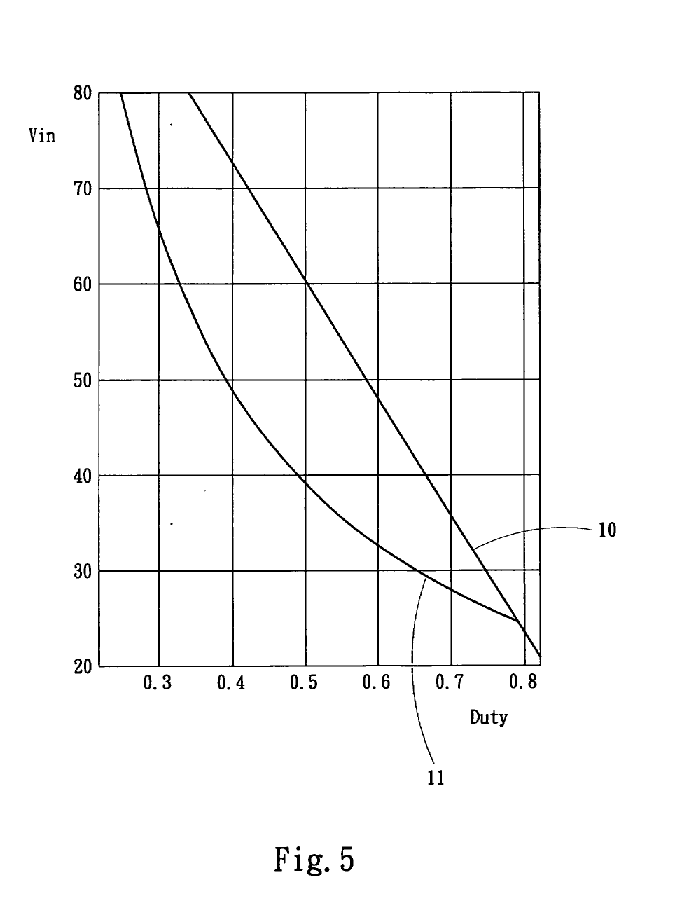

Refer to FIG. 5 for the comparison chart of input and cycle depicting the relationship of input and cycle of the driving voltage 5 output from the voltage driving unit 4. The vertical coordinate indicates the size of input voltage, the horizontal coordinate indicates the ratio value of conduction cycle. The lines represent alterations of input voltage and the conduction cycle. In order to stabilize the driving voltage 5 output from the power driving unit 4, based on the voltage second tracking theory, the conduction cycle is regulated constantly through a feedback voltage. The voltage is on the curve. Multiplication product of input and period is a constant. The line of input-cycle 11 of the work being generated is a curve. In practice, in the event that a surge or a transient voltage occurs frequency variations takes places, or the surge or transient condition has been mistakenly interpreted, the actual output could exceed the original setting curve and result in damage of the rear end circuit. The invention can control the maximum value of Vp−p by precisely controlling the oscillation waveform signal 6 to generate an upper limit 10 of input-cycle. The input voltage value and alteration amount of the high level cycle width of the pulse width control signal 8 form a linear relationship. The upper limit 10 of the input-cycle is a straight line which represents the maximum limitation of the driving voltage 5. Namely whether floating or surge occurs to the input voltage, the driving voltage 5 always is being controlled below the upper limit 10 of the input-cycle. The invention limits the allowable maximum conduction cycle of the pulse width control signal 8 through the oscillation waveform signal 6 and the waveform signal level 7, thereby forms a fixed peak value for the driving voltage 5. As a result, design of the voltage-resistant elements can be done according the upper limit of the peak value of the driving voltage 5 to enhance circuit safety and reduce cost. While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A cycle modulation circuit having a capability to limit peak voltage providing a pulse width control signal to a rear end power driving unit, comprising:
a comparison unit which has signal input ends and a signal output end to output the pulse width control signal;
an input voltage source to generate a waveform signal level of an input voltage value to be sent to one signal input end of the comparison unit; and
a linear voltage generation unit to generate an oscillation waveform signal of a linear voltage value to be sent to another signal input end of the comparison unit;
wherein the comparison unit compares the level of the oscillation waveform signal against a base value of the waveform signal level to modulate and output the pulse width control signal which has a combined cycle consisting of a high level and a low level, the pulse width control signal being input to the rear end power driving unit to limit the power driving unit in an equal restricted voltage peak value zone and determine the allowable duty cycle according to the level waveform signal.

2. The cycle modulation circuit of claim 1, wherein the 1 waveform signal level has an input voltage value generated by the input voltage source linking to a voltage dividing unit in an attenuation condition.

3. The cycle modulation circuit of claim 1, wherein the oscillation waveform signal generated by the linear voltage generation unit is in a linear voltage saw type waveform at a potential difference.

4. The cycle modulation circuit of claim 1, wherein the input voltage value and the high level cycle width of the pulse width control signal are in an inverse proportional relationship.

5. The cycle modulation circuit of claim 1, wherein the input voltage value and alterations of the high level cycle width of the pulse width control signal are in a linear relationship.
